(19) United States
(12) Patent Application Publication
(10) Pub. No.: US 2014/0183334 A1
(43) Pub. Date: Jul. 3, 2014

(54) IMAGE SENSOR FOR LIGHT FIELD DEVICE AND MANUFACTURING METHOD THEREOF

(71) Applicants: Wei-Ko WANG, Longtan Township (TW); Chin-Ching CHANG, Hsinchu City (TW); Chia-Hui WU, Lunbei Township (TW); Chien-Hsiung HUANG, Hsinchu City (TW); Cheng-Xuan LIN, Hukou Township (TW); Chieh-Yuan CHENG, Hsin-Chu City (TW); Chang Wei CHEN, Kaohsiung City (TW)

(72) Inventors: Wei-Ko WANG, Longtan Township (TW); Chin-Ching CHANG, Hsinchu City (TW); Chia-Hui WU, Lunbei Township (TW); Chien-Hsiung HUANG, Hsinchu City (TW); Cheng-Xuan LIN, Hukou Township (TW); Chieh-Yuan CHENG, Hsin-Chu City (TW); Chang Wei CHEN, Kaohsiung City (TW)

(73) Assignee: VisEra Technologies Company Limited, Hsin-Chu City (TW)

(21) Appl. No.: 13/733,691

(22) Filed: Jan. 3, 2013

(51) Int. Cl. H01L 27/146

(52) U.S. Cl. CPC H01L 27/14627; H01L 27/14685
USPC 250/208.1; 438/70

(57) ABSTRACT

An image sensor for light field devices includes a plurality of sub-microlenses, a space layer, and a plurality of main microlenses. The space layer is disposed on the sub-microlenses, and the main microlenses are disposed on the space layer. The diameter of each of the main microlenses exceeds that of each of the sub-microlenses.

### BACKGROUND OF THE INVENTION

1. Field of the Invention

The invention relates to an image sensor, and in particular, to an image sensor for light field cameras.

2. Description of the Related Art

A light-field camera is a camera that uses a microlens array to capture 3D light field information of a scene. Therefore, a user can refocus the image generated by the light-field camera. FIG. 1 is a schematic view of a conventional light field camera A1. FIG. 2 is an exploded view of a conventional image sensor A2. The light field camera A1 includes a lens A2 and an image sensor A3, and the image sensor A3 includes a microlens array A10, a sensing array A20, and a frame A30. The microlens array A10 is separated from the sensing array A20 by a predetermined distance by the frame A30.

A light beam of an object B1 is emitted to the lens A2, and when the light beam is focused on the microlens array A10, the light beam is emitted to the sensing array A20. Thus, the light beam from the microlens A11 of the microlens array A10 must accurately be emitted to several predetermined sensing units A21 of the sensing array A20. Thus, the position relating to the microlens array A10 and the sensing array A20 is very important for proper performance of the light-field camera A1. However, as shown in FIG. 2, since the image sensor A3 is made by assembling the microlens array A10, the sensing array A20, and the frame A30 together, there is a large tolerance between the microlens array A10 and the sensing array A20.

Conventionally, the position may be adjusted by some mechanism, such as screws A40 and springs A50 of the image sensor A3. However, a lot of time is needed to correct the relative positions of the microlens array A10 and the sensing array A20 for every image sensor A2. Moreover, the relative position may be changed when impact to the light field camera A1 occurs.

### BRIEF SUMMARY OF THE INVENTION

To solve the problems of the prior art, the invention provides an image sensor having accurate relative positions of main microlenses and sub-microlenses.

The invention provides an image sensor for light field devices including a plurality of sub-microlenses, a space layer, and a plurality of main microlenses. The space layer is disposed on the sub-microlenses. The main microlenses are disposed on the space layer. The diameter of each of the main microlenses exceeds that of each of the sub-microlenses.

The invention provides a manufacturing method of an image sensor including the following steps: providing a sensing layer; forming a plurality of sub-microlenses on the sensing layer; forming a space layer on the sub-microlenses by a semiconductor process; and forming a plurality of main microlenses on the space layer, wherein a diameter of each of the main microlenses exceeds that of each of the sub-microlenses.

In conclusion, since the image sensor is manufactured by a semiconductor process and formed as a single piece, the relative positions of the main microlenses and sub-microlenses are accurate and fixed.

### BRIEF DESCRIPTION OF THE DRAWINGS

The invention can be more fully understood by reading the subsequent detailed description and examples with references made to the accompanying drawings, wherein:

FIG. 1 is a schematic view of a conventional light field camera;

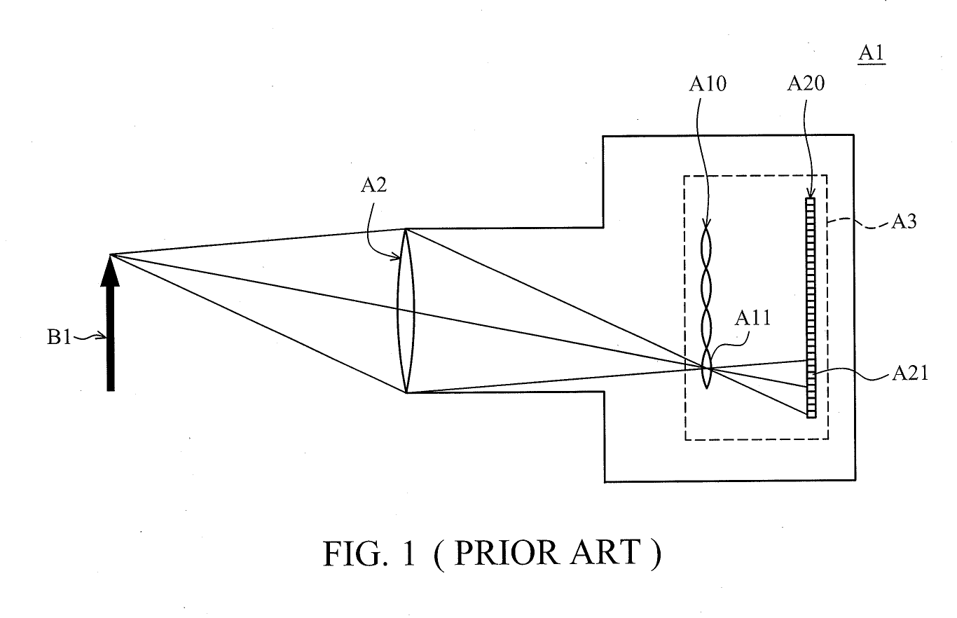

FIG. 2 is an exploded view of a conventional image sensor;

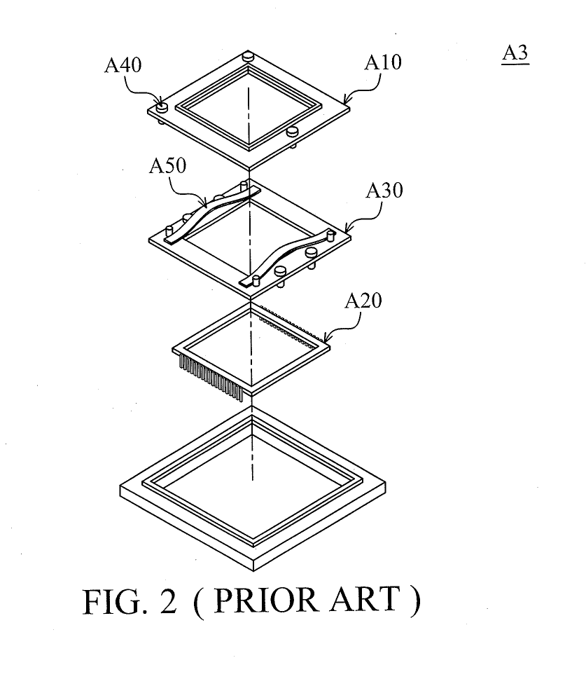

FIG. 3 is a schematic view of a light-field device according to a first embodiment of the present disclosure;

FIG. 4 is a cross sectional view of an image sensor according to the first embodiment of the present disclosure;

FIG. 5 is a cross sectional view of an image sensor according to the second embodiment of the present disclosure;

FIG. 6 is a top view of the image sensor according to the second embodiment of the present disclosure; and

FIG. 7 is a flow chart of a manufacturing method of an image sensor according to the described embodiment of the present disclosure.

### DETAILED DESCRIPTION OF THE INVENTION

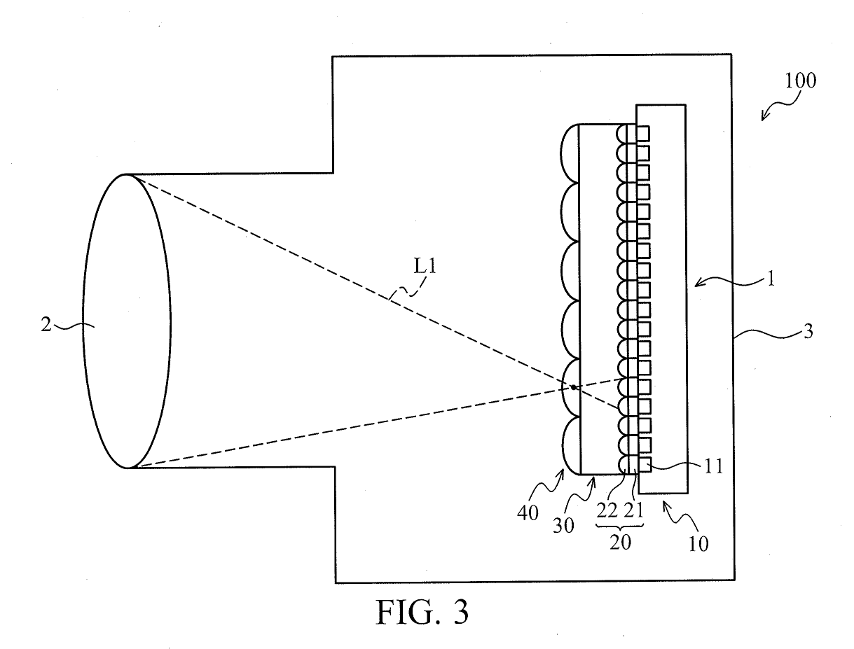

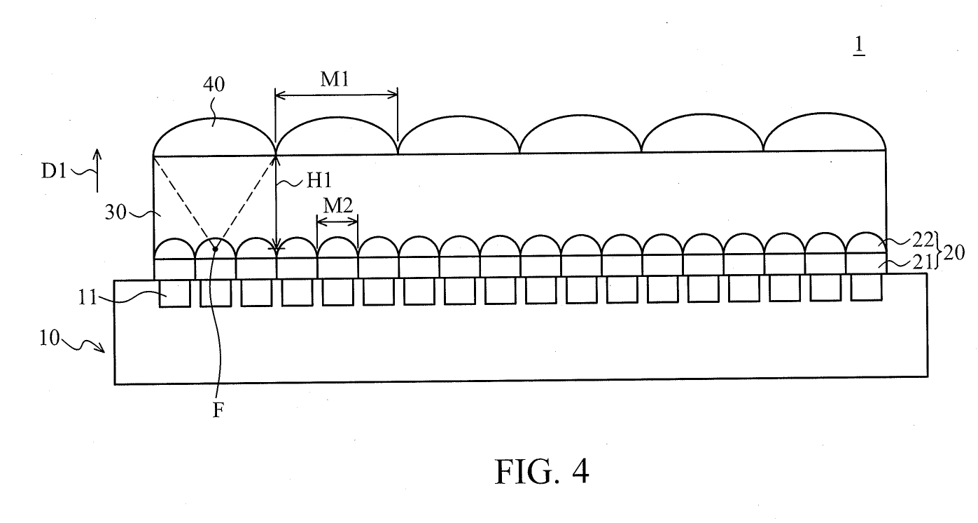

FIG. 3 is a schematic view of a light-field device 100 according to a first embodiment of the present disclosure. FIG. 4 is a cross sectional view of an image sensor 1 according to the first embodiment of the present disclosure. The light-field device 100 may be a light-field camera, or a light-field camera module disposed in an electronic device, such as a mobile phone or a portable computer.

The light-field device 100 includes an image sensor 1, a lens 2, and a housing 3. The image sensor 1 is disposed in the housing 3, and the lens 2 is disposed on the housing 3. A light beam L1 passes through the lens 2 into the housing 3, and is emitted to the image sensor 1.

The image sensor 1 includes a sensing layer 10, a filter structure 20, a space layer 30, and main microlenses 40. The sensing layer 10, the filter structure 20, the space layer 30, and one of the main microlenses 40 are stacked to each other, and arranged along a direction D1 in sequence. The sensing layer 10 includes sensing units 11.

The filter structure 20 is disposed on the sensing layer 10, and includes filter units 21 and sub-microlenses 22. Each of the filter units 21 is disposed on one of the sensing units 11, and each of the sub-microlenses 22 is disposed on one of the filter units 21.

The sub-microlenses 22 include SiN, TiO₂, Ta₂O₅, or HfO₂, and are transparent. A refractive index of the sub-microlenses 22 is greater than 1.7, and may be 1.8 to 1.9. In the embodiment, the sub-microlenses 22 include about 90 wt % or greater SiN, TiO₂, Ta₂O₅, or HfO₂. The refractive index of the sub-microlenses 22 is about 1.8. In this present disclosure, the refractive index is defined as a refractive index of a light beam with a wavelength of 589 nm.

The space layer 30 is disposed on the sub-microlenses 22. The space layer 30 includes SiO₂, MgF₂, or SiON, and is transparent. A refractive index of the space layer 30 is lower than 1.7, and may be 1.3 to 1.6. The thickness of the space layer 30 is 100 um to 150 um. In the embodiment, the space layer 30 includes about 90 wt % or greater SiO₂, MgF₂, or SiON. The refractive index of the space layer is about 1.46, and the thickness of the space layer 30 is about 120 um.

The main microlenses 40 are disposed on the space layer 30. The main microlenses 40 include SiO₂, MgF₂, or SiON, and are transparent. A refractive index of the main microlenses 40 is lower than 1.7, and may be 1.3 to 1.6. In the embodiment, the main microlenses 40 include about 90 wt % or greater SiO₂, MgF₂, or SiON. The refractive index of the main microlenses 40 is about 1.46 as the same as the space layer 30.

A diameter M1 of each of the main microlenses 40 exceeds a diameter M2 of each of the sub-microlenses 22. The diameter M1 is about 10 um to 150 um, and the diameter M2 is about 1 um to 10 um. The diameter M1 is 2 times to 20 times that of the diameter M2. In the embodiment, the diameter M1 is 3 times that of the diameter M2. One of the main microlenses 40, the sub-microlenses 22, the filter units 21, and the sensing units 11 are arranged along the direction D1 in sequence. The sensing units 11, the filter units 21, the sub-microlenses 22, and the main microlenses 40 are arranged in an array, and respectively arranged in a plane, wherein the direction D1 is perpendicular to the planes.

Each of the main microlenses 40 has a focal length H1 and a focus F. The focal length H1 is about 10 um to 150 um. In the embodiment, the focal length H1 is about 120 um. The focus F of each of the main microlenses 40 is located at one of the sub-microlenses 22. Namely, the sub-microlenses 22 and the main microlenses 40 are separated by the space layer 30, and the thickness of space layer 30 is about the focal length H1 of the main microlenses 40.

As shown in FIG. 3 and FIG. 4, the light beam LI emitted on the image sensor 1 passes through the main microlenses 40, the space layer 30, the sub-microlenses 22, the filter units 21, and the sensing units 11. The filter units 21 have various colors, such as red, green, and/or blue. When the light beam L1 passes through the filter units 21, the color of the light beam L1 is changed according to the color of the filter units 21. Next, each of the sensing units 11 generates a signal according to the light beam L1 emitted thereon, and the light-field device 100 generates an image according to the signals. Note that since the sensing units 11, the filter units 21 and generating an image according to the signals are prior art, further descriptions thereof are not included.

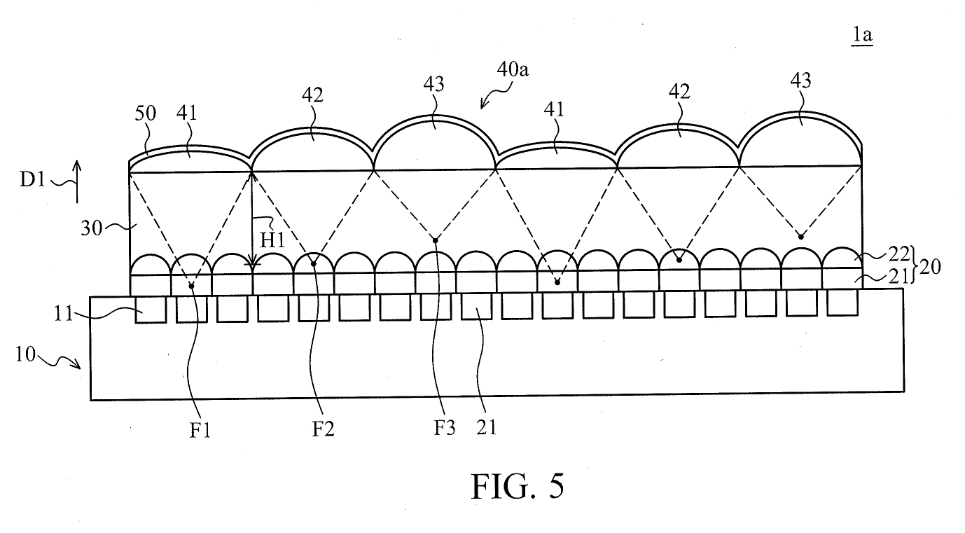

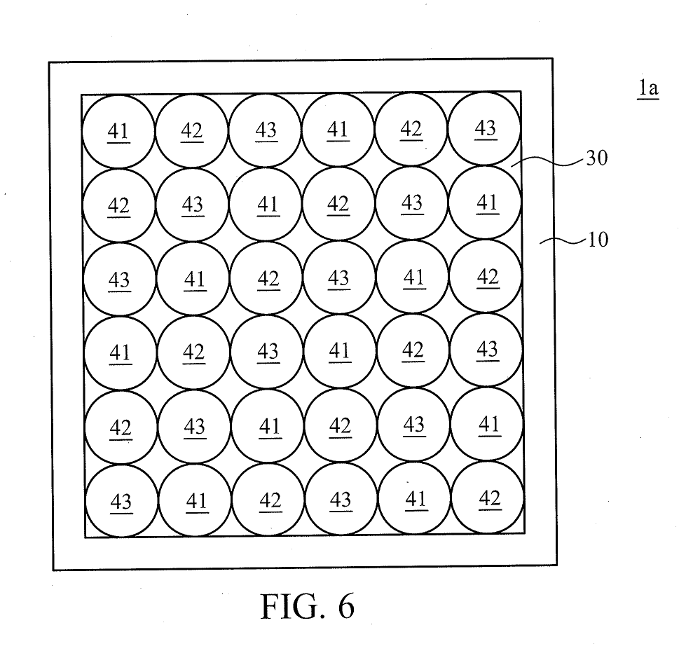

FIG. 5 is a cross sectional view of an image sensor 1a according to the second embodiment of the present disclosure. FIG. 6 is a top view of the image sensor 1a according to the second embodiment of the present disclosure. The differences between the second embodiment and the first embodiment are described as following. The main microlenses 40a include first microlenses 41, second microlenses 42 and third microlenses 43, and an anti-reflective coating layer 50 disposed on the main microlenses 41, 42 and 43. However, the anti-reflective coating layer 50 is an optional.

Each of the first microlenses 41 has a focus F1, each of the second microlenses 42 has a focus F2, and each of the third microlenses 43 has a focus F3. The focal length of each of the first microlenses 41 exceeds that of each of the second microlenses 42, and a focal length HI of each of the second microlenses 42 exceeds that of each of the third microlenses 43. As shown in FIG. 6, the first microlenses 41, the second microlenses 42, and the third microlenses 43 are arranged alternately in a plane.

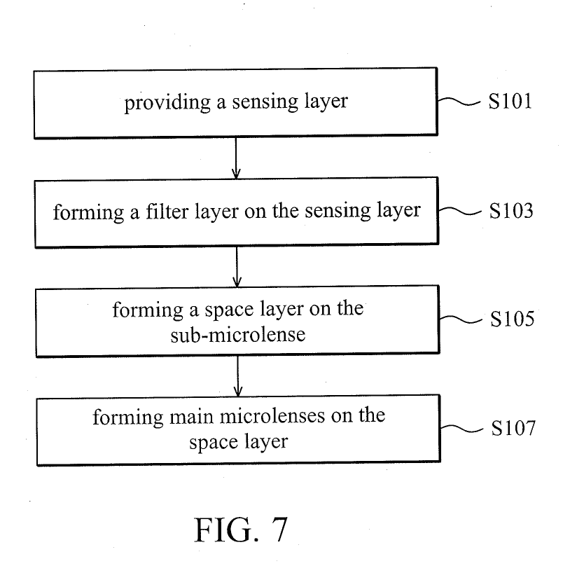

FIG. 7 is a flow chart of a manufacturing method of an image sensor according to the described embodiment of the present disclosure. First, in step S105, a sensing layer 10 is provided, and the sensing units 11 of the sensing layer 10 is made by a semiconductor process.

The filter structure 20 is formed on the sensing layer 11 (step S103). In step S103, the filter units 21 are formed on the sensing layer 10 by a semiconductor process, such as lithography, reflowing, or etching process. Next, the sub-microlenses 22 are formed on the filter units 21 by semiconductor process, such as lithography, reflowing, or etching process.

In step S105, the space layer 30 is formed on the sub-microlenses 22 by a semiconductor process, such as lithography, reflowing, or etching process. Finally, in step S107, the main microlenses 40 are formed on the space layer 30 by a semiconductor process, such as lithography, reflowing, or etching process, and the anti-reflective coating layer 60 is formed on the main microlenses 40 by a semiconductor process, such as lithography, reflowing, or etching process.

Since the image sensor 1 is manufactured by a semiconductor process and formed as a single piece, the distance and the horizontal displacement between the sub-microlenses 22 and the main microlenses 40 is accurate and fixed. The tolerance between the sub-microlenses 22 and the main microlenses 40 may be controlled to several nanometers. The time of adjustment of the relative positions of the sub-microlenses 22 and the main microlenses 40 for each image sensor 1 is omitted.

In conclusion, since the image sensor is manufactured by a semiconductor process and formed as a single piece, the relative positions of the main microlenses and sub-microlenses are accurate and fixed.

Although a feature may appear to be described in connection with a particular embodiment, one skilled in the art would recognize that various features of the described embodiments may be combined.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An image sensor for light field devices, comprising:
a plurality of sub-microlenses;
a space layer disposed on the sub-microlenses; and
a plurality of main microlenses disposed on the space layer,
wherein a diameter of each of the main microlenses exceeds that of each of the sub-microlenses.

2. The image sensor as claimed in claim 1, further comprising a plurality of filter units, wherein each of the sub-microlenses is disposed on one of the filter units.

3. The image sensor as claimed in claim 2, further comprising a sensing layer comprises a plurality of sensing units, wherein each of the filter units is disposed on one of the sensing units.

4. The image sensor as claimed in claim 1, wherein the diameter of each of the main microlenses is 2 times to 20 times that of the diameter of each of the sub-microlenses.

5. The image sensor as claimed in claim 1, wherein a refractive index of the space layer is lower than 1.6.

6. The image sensor as claimed in claim 5, wherein a refractive index of each of the main microlenses is the same as the space layer.

7. The image sensor as claimed in claim 1, wherein a refractive index of each of the main microlenses is lower than 1.7.

8. The image sensor as claimed in claim 1, wherein a refractive index of each of the sub-microlenses is greater than 1.7.

9. The image sensor as claimed in claim 1, wherein the space layer includes SiO₂, and is transparent.

10. The image sensor as claimed in claim 1, wherein the main microlenses include SiO₂, MgF₂, or SiON, and the sub-microlenses include SiN, TiO₂, Ta₂O₅, or HfO₂.

11. The image sensor as claimed in claim 1, wherein a focus of each of the main microlenses is located at one of the sub-microlenses.

12. The image sensor as claimed in claim 1, wherein the main microlenses include a plurality of first microlenses and a plurality of the second microlenses, and a focal length of each of the first microlenses exceeds that of each of the second microlenses, and the first microlenses and the second microlenses are arranged alternately.

13. The image sensor as claimed in claim 1, wherein the main microlenses include a plurality of first microlenses, a plurality of second microlenses and a plurality of third microlenses, and a focal length of each of the first microlenses exceeds that of each of the second microlenses, and a focal length of each of the second microlenses exceeds that of each of the third microlenses, and the first microlenses, the second microlenses, and the third microlenses are arranged alternately.

14. The image sensor as claimed in claim 1, comprising an anti-reflective coating layer disposed on the main microlenses.

15. A manufacturing method of an image sensor, comprising:
providing a sensing layer;
forming a plurality of sub-microlenses on the sensing layer;
forming a space layer on the sub-microlenses by a semiconductor process; and
forming a plurality of main microlenses on the space layer, wherein a diameter of each of the main microlenses exceeds that of each of the sub-microlenses.

16. The manufacturing method as claimed in claim 15, further comprising forming a plurality of filter units on the sensing layer, wherein each of the sub-microlenses is disposed on one of the filter units.

17. The manufacturing method as claimed in claim 16, wherein the sensing layer comprises a plurality of sensing units, and each of the filter units is disposed on one of the sensing units.

18. The manufacturing method as claimed in claim 15, wherein the space layer includes SiO₂, and is transparent.

19. The manufacturing method as claimed in claim 15, wherein the main microlenses include SiO₂, MgF₂, or SiON, and the sub-microlenses include SiN, TiO₂, Ta₂O₅, or HfO₂.

20. The manufacturing method as claimed in claim 15, comprising forming an anti-reflective coating layer on the main microlenses.
